(19) United States
(12) Patent Application Publication
(10) Pub. No.: US 2003/0054616 A1
(43) Pub. Date: Mar. 20, 2003

(54) Electronic devices and methods of manufacture

(75) Inventors: Denis H. Endisch, Cupertino, CA (US); Joseph Levert, Vista, CA (US)

Correspondence Address: Sandra P. Thompson, Rutan and Tucker, LLP, 611 Anton Boulevard, Fourteenth floor, Costa Mesa, CA, 92626-1998, US

(73) Assignee: Honeywell International Inc.

(21) Appl. No.: 09/943,237

(22) Filed: Aug. 29, 2001

(51) Int. Cl. H01L 29/00

(52) U.S. Cl. 438/400

(57) ABSTRACT

An electronic device comprises a substrate with a trench having a lower portion and a top portion. The lower portion of the trench is filled with a cured spin-on compound, while the top portion is filled with a chemical vapor-deposited compound. Preferably, the chemical vapor-deposited compound has a surface that is substantially coplanar with the surface of the substrate. Particularly preferred methods of fabricating such devices include a step in which a trench is formed in the substrate, and in which a first compound is deposited in the trench by spin-on deposition. The first compound is partially removed from the trench to a level below the surface of the substrate, and in a further step, a second compound is deposited onto the upper surface of the first compound by chemical vapor deposition.

### FIELD OF THE INVENTION

The field of the invention is electronic devices and particularly deposition of dielectrics in microelectronic devices.

### BACKGROUND OF THE INVENTION

Dielectric isolation of active and passive devices in integrated circuits is often necessary to achieve a relatively high density of such devices and is commonly accomplished by incorporation of shallow trench isolation (STI) structures. Numerous methods of STI generation are know in the art.

In one method of forming STI structures, chemical vapor deposition (CVD) is employed to deposit the dielectric material (see e.g., U.S. Pat. No. 6,146,971 to Chen et al. (Nov. 14, 2000)). A typical process includes growth of a thermal oxide on the substrate followed by silicon nitride deposition onto the thermal oxide. The silicon nitride is subsequently patterned and etched to form a trench. A thermal oxide layer is grown in the trench, and silicon dioxide is deposited via CVD. In a further step, the silicon dioxide is reverse masked and removed from the active surface. Chemical mechanical polishing (CMP) is then employed to planarize the surface, and in a further step the silicon nitride and thermal oxide layer are etched from the surface of the substrate.

Despite various advantages of CVD deposition (e.g., CMP processes are well understood, see e.g. ULSI Technology, Chang and Sze, McGraw-Hill Co. Inc., New York, N.Y., 1996), limitations inherent to CVD tend to reduce the usefulness of such processes. For example, to avoid topographical inhomogeneities due to differential etching when the silicon nitride and thermal oxide layer is removed from the active surface, the etch rate of the CVD oxide and the thermal oxide generally need to be relatively similar, thereby limiting the choice of CVD oxides. Furthermore, and especially where the trenches have a relatively high aspect ratio (depth/width), formation of voids in the trenches during CVD tends to become more frequently.

In order to circumvent at least some of the problems, high-density plasma (HDP)-CVD may be utilized. Among other advantages, HDP-CVD combines deposition and etching, thereby significantly reducing void formation. However, HDP-CVD typically results in low throughput rates of substrates. Moreover, use of HDP-CVD tends to increase the risk of comer clipping, thereby further reducing the overall yield per production period.

Alternatively, it is known to avoid the CVD process altogether by employing spin-on materials (see e.g., U.S. Pat. No. 6,171,928 to Lou (Jan. 9, 2001)). Spin-on materials often exhibit superior planarization properties when compared to CVD materials. Furthermore, spin-on materials typically have desirable gap filling capability. Thus, alternative methods of forming an STI structure include growth of a thermal oxide on the substrate (also called pad oxide), and silicon nitride deposition onto the thermal oxide. The silicon nitride is subsequently patterned and etched to form a trench. A thermal oxide layer is grown in the trench (also called liner oxide), and a spin-on compound is spun onto the substrate, which is subsequently cured. In a following CMP step, the wafer is planarized and the silicon nitride/thermal oxide is etched from the active surface.

Despite the relatively simple process employing spin-on materials, several disadvantages persist, and particularly include shrinkage of the spin-on material within the trench during the cure step. Low-density cured spin-on material inside the trench has a significantly higher (about 3-10 times) wet rate than the thermal oxide, and is therefore no more compatible with etch steps after curing (e.g., etching of the silicon nitride/thermal oxide from the active surface).

Thus, various methods of fabricating electronic devices are known in the art, however, all or almost all of them suffer from one or more disadvantages. Therefore, there is still a need to provide improved methods and apparatus for electronic devices.

### SUMMARY OF THE INVENTION

The present invention is directed to configurations and production of electronic devices that include a substrate with a trench having a lower portion and a top portion. The lower portion of the trench is filled with a spin-on compound, and the top portion is filled with a CVD material. Preferably, the CVD material has a surface that is substantially coplanar with the surface of the substrate.

In one aspect of the inventive subject matter, the trench further comprises a thermal oxide coat (liner), and particularly contemplated trenches have an aspect ratio (depth/width) of no less than 5, and more preferably no less than 8. The lower portion of preferred trenches extends up to 60%, and more preferably up to 80% of the height of the trenches. It is further contemplated that the trench is an element of a shallow trench isolation structure (STI).

In another aspect of the inventive subject matter, the spin-on compound comprises silicon and is preferably formed from methylsilsesquioxane, hydrogensilsesquioxane, methylhydridosilsesquioxane, silicate, or perhydrosilazane. Preferred chemical vapor-deposited (CVD) compounds comprise silicon, and especially preferred CVD compounds are formed from silane or tetraethylorthosilicate.

In a further aspect of the inventive subject matter, a particularly preferred method of manufacturing such devices includes a step in which a trench is formed in the substrate, and in which a first compound is deposited in the trench by spin-on deposition. The first compound is partially removed from the trench to a level below the surface of the substrate, and in a further step, a second compound is deposited onto the upper surface of the first compound by chemical vapor deposition.

In a still further contemplated aspect of the inventive subject matter, the first compound is partially removed by a spin-rinse process, a wet etch process, or a dry etch process. Contemplated first compounds include methylsilsesquioxane, hydrogensilsesquioxane, methylhydridosilsesquioxane, silicate, and perhydrosilazane, and contemplated second compounds include tetraethylorthosilicate and silane.

Various objects, features, aspects and advantages of the present invention will become more apparent from the following detailed description of preferred embodiments of the invention, along with the accompanying drawing.

### BRIEF DESCRIPTION OF THE DRAWING

FIG. 1A is a schematic vertical cross section of a prior art electronic device.

FIG. 1B is a schematic vertical cross section of an electronic device according to the inventive subject matter.

FIG. 2 is a flow chart of an exemplary method of producing an electronic device according to the inventive subject matter.

### DETAILED DESCRIPTION

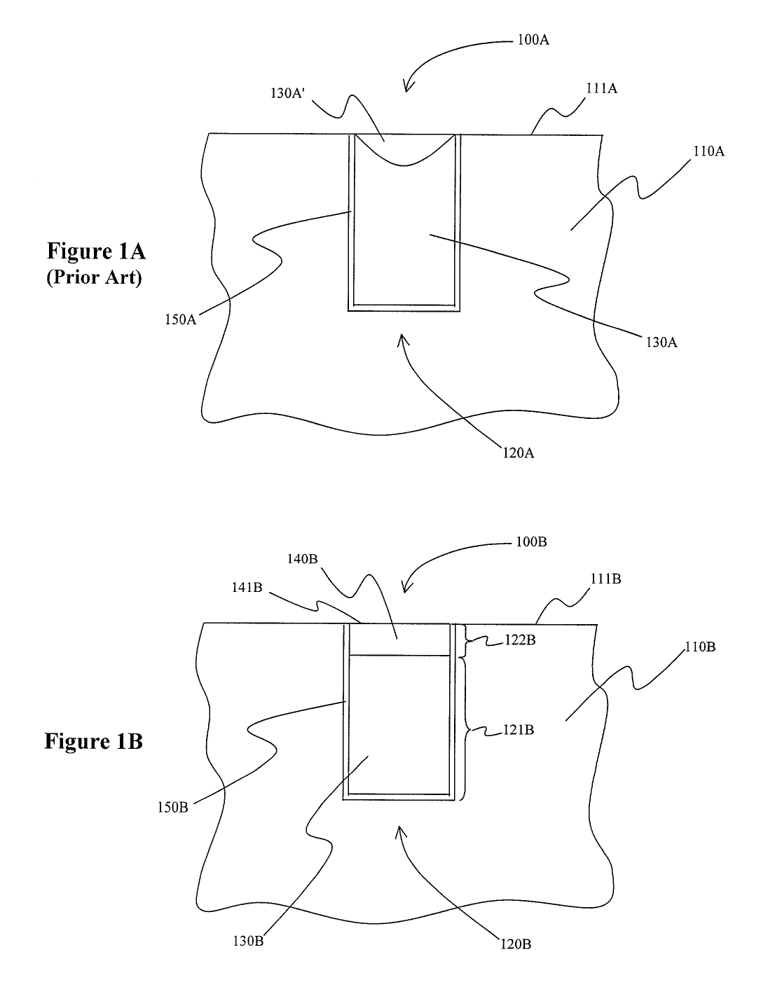

It is known in the art, that STI structures exclusively filled with either a CVD compound or a spin-on compound often exhibit various disadvantages (supra). A relatively common disadvantage is depicted in prior art FIG. 1A, in which an electronic device 100A has a substrate 110A with surface 111A and trench 120A. The trench 120A further has a thermal oxide coat (liner) 150A, and the trench is filled with a cured spin-on compound. Due to the dimensional constraint in the trench during the curing step, the lower portion (with respect to the surface) 130A of the cured spin-on dielectric material has a lower density than the upper portion (with respect to the surface) 130A′ of the cured spin-on dielectric material, typically resulting in differential etching behavior in subsequent processing steps.

The inventors have discovered that dielectric materials can be deposited on an electronic device employing both spin-on and CVD materials, and that such deposited structures exhibit numerous advantageous over known structures. In FIG. 1B, an electronic device 100B comprises a substrate 110B with a surface 111B and trench 120B. The trench 120B is further coated with a thermal oxide coat (liner) 150B. A lower portion of the trench 121B is filled with a cured spin-on compound 130B, while a top portion of the trench 122B is filled with a CVD deposited compound 140B. The CVD deposited compound 140B has a surface 141B, which is coplanar with the surface of the substrate 111B.

In particularly preferred aspects of the inventive subject matter, the electronic device 100B is an integrated circuit, wherein the substrate 110B is a silicon wafer with a substantially planar surface 111B. Trench 120B is etched into the substrate and is further coated with a thermal oxide coat 150B. The lower portion of the trench 121B extends upwards from the bottom of the trench to a height of 60% of the height of the trench and is filled with cured hydrogensilsesquioxane 130B, which has been spun onto the substrate 110B. The top portion of the trench 122B (corresponding to the remaining 40% of the height of the trench) is filled with silicon dioxide formed from CVD deposited silane 140B. The CVD deposited silicon dioxide 140B has a surface 141B, which is substantially coplanar (i.e. having a maximum vertical offset of 20 nm) with the surface of the silicon substrate 111B.

With respect to the substrate, it should be appreciated that while silicon wafers and other silicon-based semiconductor substrates are particularly preferred, numerous substrates other than silicon wafers may also be utilized, and alternative substrates include non-silicon semiconductor materials (e.g., germanium-based or gallium-based) and inorganic/organic dielectric materials (e.g., polysilicates, poly(arylene ethers), etc.)

It is generally contemplated that the substantially planar surface 111B of the substrate 110B is the surface of a silicon wafer. As used herein, the term “surface” refers to any area of the substrate onto which functional elements (e.g., conductive traces or vias) are formed. As further used herein, the term “substantially planar surface” means that the surface has been subjected to a planarization process (e.g., chemical mechanical planarization (CMP)) and has an unevenness of no more than about 5 nm to 20 nm between the highest point and the lowest point on the surface. In alternative aspects of the inventive subject matter, the surface may further include alternative materials, including functional and non-functional material. For example, functional materials may include dielectric materials, thermal oxide, and metals, while non-functional material may include an etch-stop layer (e.g., silicon nitride) or other masking material.

It is also contemplated that suitable trenches are etched into the substrate and will typically have a width between about 50 nm to 500 nm and a depth between about 400 nm to 700 nm. However, greater widths of between approximately 500 nm to 5000 nm and more are also contemplated. Similarly, contemplated trenches need not be limited to a particular depth, and it is contemplated that the depth of appropriate trenches will be between about 200 nm to 2000 nm, or more. Although the aspect ratio (depth to width) of contemplated trenches is not limited to a particular number or range, it is particularly contemplated that preferred aspect ratios are no less than 5 (e.g., between 5 and 10), more preferably no less than 8, and most preferably no less than 10 (e.g., between 10 and 15). Likewise, it should be recognized that the layout (i.e., path) of contemplated trenches may vary considerably, and contemplated layouts include linear, circular, and curved trenches, and all reasonable combinations thereof. While it is generally contemplated that suitable trenches are etched into the substrate, it should be recognized that the manner of trench formation is not limiting to the inventive subject matter. Consequently, trenches formed by alternative methods are also contemplated and include additive (i.e., trench formation by adding walls to a surface) and subtractive (i.e., trench formation by removing material from a surface) methods.

Where appropriate, contemplated trenches may further comprise additional layers or coatings coupled to at least a portion of the floor and/or sidewall of the trench. For example, contemplated additional layers or coatings may include a thermal oxide coat, one or more organic and/or inorganic dielectrics, metals, polysilicon, etc. There are numerous methods of forming trenches in a silicon substrate known in the art, and all of the known methods are contemplated suitable for use in conjunction with the teachings presented herein.

With respect to the spin-on compound, it is contemplated that all known spin-on dielectrics are suitable for use herein and include inorganic and organic spin-on compounds that may or may not require a further curing step to produce the dielectric. For example, suitable organic spin-on dielectrics include conjugated and non-conjugated aromatic polymers (e.g., polyimides, polyarylenes, etc.) and non-aromatic polymers (e.g., epoxy networks, cyanate ester resins, etc.). Suitable inorganic spin-on dielectrics include various compounds comprising silicon, and especially contemplated inorganic spin-on compounds are methylsilsesquioxane, hydrogensilsesquioxane, methylhydridosilsesquioxane, silicate, and perhydrosilazane. Useful organohydridosiloxanes are disclosed in commonly assigned U.S. Pat. Nos. 6,143,855 and 6,043,330, incorporated herein by reference. One particularly useful organohydridosiloxane is commercially available from Honeywell International Inc. as HOSP™ spin-on dielectric. Particular spin-on and curing conditions for a particular application will typically depend on the type of spin-on compound, trench depth, desired degree of curing, and will readily be determined by a person of ordinary skill without undue experimentation.

It is generally contemplated that the lower portion of the trench is filled with the spin-on compound. As used herein, the term “lower portion” refers to a volume of the trench that extends from the floor (i.e., the lowest portion of the trench with respect to the surface of the substrate) of the trench to any height of the trench that is below the surface of the substrate. Consequently, it is contemplated that the lower portion of the trench may extend from the floor of the trench up to 10% of the depth (i.e., the maximum vertical distance between the floor of the trench and the surface of the substrate) of the trench, preferably up to 40%, more preferably up to 60%, and even more preferably up to 80%, and most preferably between 80% and 95% of the depth of the trench. It should be recognized that the use of a spin-on compound to form a dielectric in the trench is especially advantageous where the trench has a relatively high aspect ratio (i.e., greater than 5), since increasing aspect ratios often result in void formation during a typical CVD process.

It is further contemplated that the CVD deposited compound preferably has an etch resistance similar to thermal oxide (i.e., etch rate between 1 and 3 times of etch rate of thermal oxide, preferably between 1 and 2 times, more preferably between 1 and 1.5 times), and have well understood CMP conditions. For example, appropriate CVD deposited compounds comprise silicon, and particularly preferred CVD deposited compounds are formed from silane or tetraethylorthosilicate (TEOS). However, in alternative aspects, known CVD compounds other than silicon comprising compounds are also contemplated suitable for use herein. With respect to the deposition of the CVD compound, it should be appreciated that particular conditions may vary considerably (i.e., HDP-CVD, low pressure (LP)-CVD, atmospheric pressure (AP)-CVD, plasma enhanced (PE)-CVD) and will depend on particular materials employed. It is further contemplated that the upper portion of the trench will be filled with the CVD deposited compound. As used herein, the term “upper portion” of the trench refers to the volume of the trench between the surface of the substrate and the lower portion of the trench. It should further be appreciated that one or more additional layers may be disposed between the cured spin-on compound and the CVD compound, and contemplated additional layers include functional (e.g., dielectric, conductive, semiconductive) and non-functional layers (e.g., adhesion promoters). While not critical to the inventive subject matter, it is particular preferred that the upper surface of the CVD compound is substantially coplanar with substrate surface (i.e. has a maximum vertical offset of 50 nm). There are various methods of coplanarization known in the art, and all of the known methods are contemplated suitable for use herein. Particularly preferred method is CMP.

Thus, a method of forming an electronic device according to the inventive subject matter includes one step in which a trench is formed in a substrate having a surface, and a first compound is deposited into the trench using spin-on deposition. In a further step, the first compound is partially removed from the trench such that an upper surface of the compound in the trench is below the surface of the substrate. In yet another step, a second compound is deposited onto the surface and onto the upper surface of the first compound by CVD. With respect to the substrate, the surface of the substrate, the trench, the spin-on compound (i.e., the first compound), and the CVD deposited compound (i.e., the second compound), the same considerations as discussed apply.

While it is contemplated that all known methods of partially removing the spin-on compound from the trench are suitable (e.g., wet etch or dry etch), it is particularly preferred that the partial removal is achieved by a spin-rinse process (infra). Contemplated spin-rinse processes comprise a step in which a solvent mixture is spun onto a spin-on film (e.g., the spin-on compound in the trench), which may or may not be partially or completely cured. The solvent mixture generally comprises at least one solvent (i.e., a composition that breaks down and/or dissolves the spin-on film, also referred to as active component) and at least one non-solvent (i.e., a composition that is inert to the spin-on film or that breaks down and/or dissolves the spin-on film at a rate of at least 10 times less than the solvent). While miscibility of the solvent and the non-solvent is not critical, it is preferred that solvent mixtures comprise solvents that are miscible with the non-solvent. The choice of a particular solvent will typically depend on the composition of the spin-on film and on the desired rate of removal. However, it is generally contemplated that all known solvents are suitable for use herein, and contemplated solvents include aqueous and non-aqueous solvents, acids, and bases, all of which may be selected by various criteria, including polarity, hydrophobicity, miscibility, etc.

Consequently, it is contemplated that a method of removing a spin-on compound comprises a step in which a spin-on compound is deposited on a surface of a substrate. In a further step, the spin-on compound is spin-rinsed with a solvent mixture, wherein the solvent mixture comprises a first solvent that dissolves the spin-on compound, and a second solvent that is inert to the spin-on compound. Particularly contemplated spin-on compounds comprise silicon, while the first solvent comprises propyl acetate, and the second solvent comprises ethyl lactate. However, various alternative solvents are also contemplated. For example, the first solvent may be a ketone (e.g., MIBK), an ester (e.g., propyl acetate), an ether (e.g., PGMEA), a hydrocarbon (e.g., hexane), and the second solvent may be water, an alcohol (e.g., ethanol, methanol), acetonitrile, an amine, or an amide. It is still further contemplated that suitable substrates are heated to a first temperature to remove the solvent mixture, and then heated to a second temperature to cure the spin-on compound.

It should especially be appreciated that the removal rate and the degree of planarization (DOP) of the spin-on film in contemplated spin-rinse processes can advantageously be controlled through various parameters, including solvent choice and ratio, spin conditions, temperature, dispense profile and volume, etc. For example, a higher ratio of solvent to non-solvent in the solvent mixture will generally result in a higher removal rate. The DOP can typically be controlled utilizing micro-loading inside narrow features. Micro-loading occurs inside narrow and dense features (trenches) when the active component becomes saturated with the removed material quicker than it is replaced by fresh solvent. The micro-loading effect is caused by the fluid dynamics inside a trench or feature, which limits the supply of fresh solvent. A low ratio of solvent to non-solvent (i.e. a low concentration of the active component) increases the effect, because the active component is saturated quicker. Micro-loading effectively reduces the relative removal rate in narrow features and dense pattern areas compared to flat areas. The improved DOP due to micro-loading is best utilized through use of a dynamic solvent application (i.e. spin rinse) instead of a static application, because fresh solvent is constantly supplied on a flat surface, whereas the solvent supply inside the narrow features is obstructed and therefore reduced. The optimal spin conditions depend on pattern design and feature density. It should also be appreciated that the spin-rinse process may also be employed in applications other than partial removal of spin-on films in the formation of a STI structure, and contemplated processes include all processes in which a spin-on film or compound needs to be at least partially removed. For example, contemplated alternative processes include processes that typically require a partial etch back (e.g., removal of dielectric material on a patterned wafer with metal wiring in an IMD application).

It is further contemplated that a spin-rinse process could also be a cost effective modification of the commonly used SOG etch back process which uses a dry etch. The SOG etch back process is often relatively expensive because several process steps are typically required: 1) Formation of metal wiring; 2) PECVD tool: Deposition of a liner oxide using CVD (this step may be omitted); 3) Spin coater: spin, bake and cure of the SOG, which fills the gaps and improves the local planarization; 4) Plasma etcher: etch back of the SOG so that less or no SOG is left on top of the metal lines (this is done to avoid ‘poisoned vias’); 5) PECVD tool: deposition of an oxide cap;. 6) CMP tool: CMP of oxide cap (this step may be omitted depending on the planarization capabilities of the SOG process and the planarization requirements of the manufacturing process. Thus, it should be particularly appreciated that contemplated processes allow eliminating a time consuming etch step (5) and generally result in a better local planarization, which may further eliminate the need for a CMP process. Consequently, it should be recognized that contemplated processes modify the spin process (4) to the following: 4a) spin coating, 4b) optional partial bake, 4c) partial removal and film planarization using the spin rinse process, 4d) bake process, 4e) cure process. A spin rinse process can be integrated into commercially available spin tracks using a conventional spin cup and does therefore not require a new process tool. Because the spin rinse process also improves the planarization as described above, the subsequent CMP process (6) may be omitted.

In still further contemplated aspects of the inventive subject matter, methods of forming an electronic device may additionally comprise a planarization step to achieve coplanarity between the surface of the substrate and the upper surface of the CVD deposited compound. Contemplated planarization steps generally include all known planarization processes, however, it is particularly preferred that the planarization is realized by CMP.

### EXAMPLES

### Spin Rinse Process

The exemplary spin rinse process described in this example may be employed as an alternative to a conventional etch-back gap fill process.

A semiconductor device structure is manufactured using standard manufacturing techniques. A metal wiring structure (2) is formed onto a semiconductor substrate (1) as depicted in structure 1. For device dimensions down to 0.18 micron, the interconnect metal is usually aluminum with small amounts of dopants. However, it is contemplated that the choice of metal is not limiting to the inventive subject matter, and other metals, including copper may also be used. However, for subtractive processes aluminum is preferred.

[image]

After deposition of the first level of metal lines (2) an optional oxide liner (3) is deposited (Structure 2). The thickness for the oxide liner is between 1 to 200 nm, with 50 nm being a typical value. The oxide liner is preferably being deposited using PECVD TEOS, although other oxides, such PECVD silane may also be used. To reduce the number of process step it is preferred not to use an oxide liner.

[image]

A spin-on material (4, see Structure 3) is then de posited as interline dielectric. The preferred thickness of the spin-on dielectric depends on the spin-on dielectric, the metal thickness and the required degree of planarization. For example, for the HOSP™ spin-on dielectric (commercially available from Honeywell Electronic Materials), for a height of the aluminum lines of 800 nm, with the narrowest gaps having a width of 500 nm, the spin-on material thickness is typically 200 to 900 nm on a blanket film, with 600 nm being preferred.

In this example, HOSP™ dielectric material is deposited using the standard spin process although the specific spin process does not have any significant influence on the application of the spin rinse process. However, in order to use the spin-rinse, the standard bake sequence is modified (standard is 1 min each at 150 degree C., 200 degree C., and 350 degree C.) so that the highest temperature used before the spin-rinse process is below 300 degree C., because HOSP™ dielectric material cannot be dissolved with an organic solvent if baked at temperatures at or above 320 degree C. The maximum temperature is of course different for other materials. The HOSP film is then exposed to a single hot plate for 1 min with a temperature between 100 degree C. to 200 degree C., with a preferred temperature of 150 degree C. The bake process allows the material to melt and reflow, thus achieving improved planarization.

[image]

A solvent mixture is then dispensed in a spin rinse process, to remove the spin-on material on top of the metal lines (see Structure 4) and improve the planarization. The spin rinse solution does not remove any materials on the substrate except the spin-on film. The rinse process takes place in a regular spin coater, but a spin etcher may also be used. The spin speed during dispense depends on the material, solvent, wafer size, tool geometry and can range from 20 rpm to 6000 rpm. 1000 rpm is a recommended spin speed during the rinse process for many applications and is used in this example. The solvent dispense rate depends on the material, solvent, wafer size, tool geometry and can range from 0.1 mL/s to 50 mL/s. 2 mL/s is a recommended dispense rate during the rinse process for many applications and is used in this example. The list of solvents for HOSP includes, but is not limited to: ketones eg. MIBK; esters, e.g. Propyl Acetate (PACE), Glycol Ether PM Acetate (PGMEA); hydrocarbons, e.g. Hexane. Non-solvents include, but are not limited to: water; alcohols (e.g. methanol, ethanol, isopropyl alcohol (IPA), ethyl lactate (EL)); acetonitrile, amines and amides. Several combinations of one or more solvent with one or more non-solvent are possible, and the preferred combination depends strongly on the material, process sequence and required removal rate for the application. In this example a 2:1 mixture of Ethyl Lactate and PACE is used as a recommended solvent mixture for the spin rinse process, and the spin rinse process is performed for a sufficient time. During the spin-rinse process, the spin-on dielectric is removed faster from the top of the metal lines than from inside the narrow gaps (microloading as explained earlier), thereby improving the planarization compared to a dry etch-back process or compared to a static wet etch. The liner oxide is not affected by the spin-rinse process, which is a benefit compared to the conventional dry etch process, which also attacks the liner oxide. At the end of the spin rinse process the wafer is spun without dispense at a spin speed of 3000 rpm for 30 sec to dry the film. The film is then baked on a hot plate for 1 min at a temperature of 350 degree C. It is then cured in a horizontal furnace for 1 hour at a temperature of 400 degree C. in a nitrogen atmosphere with a oxygen level of less than 20 ppm. At the end of the spin rinse process the spin-on material (HOSP) is removed from the top of the metal lines, while the spin-on material remains between the narrow gaps.

[image]

A CVD oxide is then deposited for the via level (see Structure 5). The thickness of the CVD oxide depends on the device structure and is typically 500 nm to 3000 nm. PECVD TEOS is typically used for this process.

[image]

Optionally the structure is then going through a chemical mechanical polishing (CMP) process. The CMP process removes part of the oxide layer and improves the planarization (Structure 6).

[image]

### Spin Etch Process

The spin etch process has certain similarities to the spin rinse process as described above, however, uses an inorganic solvent as an etchant. The spin-on material used in this example is Accuglass® 512B, which is commercially available from Honeywell. The formulation and spin speed is chosen to result in a film thickness of 500 nm on a blanket film. Accuglass 512B is deposited using the standard spin process and bake process, using a 1 min bake at 80 degree C., 150 degree C., and 250 degree C. each. The wafers are then cured in a horizontal furnace for 1 hour at a temperature of 400 degree C. in a nitrogen atmosphere with an oxygen level of less than 20 ppm (the structure looks at this time as shown in Structure 3).

An alternative curing process uses oxygen plasma ashing (with 10% nitrogen) instead of the 400C. furnace cure. This process is applicable for blanket Accuglass® 512B films up to 500 nm in thickness.

The wafers are then processed in a spin etch tool. The preferred etchant depends on the material to be etched. For this example using Accuglass® 512B spin-on material, a 10:1 to 500:1 BOE (buffered oxide etch) solution may be used, with 50:1 being preferred. The preferred spin speed during the etch process is set to 1000 rpm, the BOE flow rate is set to 0.8 lpm (liters per minute). The process time is set to 15 sec. The blanket etch rate is 140 A/s (Angstroms per second), which is about 40 times higher than the etch rate for TEOS oxide, which is used as the liner material. At the end of the spin etch process, the wafer is rinsed for 15 sec using DI (deionized) water and is then spun at a spin speed of 3000 rpm for 30 sec to dry the film. The spin rinse process will preferentially remove the material on top of the metal lines, thus improving the overall planarization. For the samples which are process using the spin etch process, the 512B material on top of the metal line is completely removed. Due to the high selectivity of the BOE for the spin-on material Accuglass® 512B the etching into the TEOS liner is less than 5 nm and therefore negligible. Subsequent steps are identical to the steps described above.

### STI Process using Spin-Rinse Process and Oxide Cap

FIG. 1B is a cross-sectional view schematically illustrating a STI structure according to a preferred aspect of the invention. The process begins with the formation of a pad oxide layer (step 1) (2 in Structure 7) on the silicon substrate (1 in Structure 7) using thermal oxidation (Structure 7). The typical thickness of the pad oxide is between 2 to 30 nm, with 10 nm being a preferred thickness.

[image]

The next process step (step 2) is the deposition of a silicon nitride layer (3 Structure 8) on to of the pad oxide (Structure 8). The typical thickness of the nitride layer is 50 to 200 nm, with 100 nm being preferred.

[image]

[image]

The next step (step 3) is the deposition of a photoresist layer over the semiconductor substrate. A photolithography (step 4) process is performed to transfer a pattern onto the substrate. Then an anisotropic etch (step 5) is performed to first open the silicon nitride (Structure 9) and then form the trench structure (4 in Structure 10).

[image]

Thermal oxidation (step 6) is then used to grow an oxide on the trench sidewall and bottom. The thickness of the trench sidewall is typically 5 to 15 nm, with 10 nm being a preferred thickness (Structure 11).

[image]

[image]

A spin-on material is then deposited inside the trench (step 7) (6 in Structure 12). The preferred thickness of the spin-on dielectric depends on the type of spin-on dielectric, the trench width and height and aspect ratio distribution. For STI structure with a trench depth of less than one micron the HOSP™ spin-on dielectric (commercially available from Honeywell Electronic Materials) is a suitable material. Typically a film thickness of 60 to 80% of the trench depth is sufficient. For a trench depth of 600 nm, a 400 nm blanket film thickness is preferred. In this example, HOSP™ spin-on dielectric is deposited using the standard spin process, although the specific spin process does not have any significant influence on the application of the spin rinse process. However, in order to use the spin-rinse, the standard bake sequence is modified (standard is 1 min each at 150 degree C., 200 degree C., and 350 degree C.) so that the highest temperature used before the spin-rinse process is below 300 degree C., because HOSP cannot be dissolved with an organic solvent if baked at temperatures at or above 320 degree C. The maximum temperature is of course different for other materials. The HOSP film is then exposed to a single hot plate for 1 min with a temperature between 100 degree C. to 200 degree C., with a preferred temperature of 150 degree C. The bake process allows the material to melt and reflow, thus achieving improved planarization.

[image]

The HOSP™ film is then partially removed using a spin-rinse process (step 8). A solvent mixture is dispensed in the spin rinse process, which removes all HOSP polymer from the top of the nitride layer (Structure 13) (using the same procedure as described in the spin rinse process above). The spin rinse time is adjusted so that the top surface of the HOSP film is between 20 to 200 nm below the substrate surface for the narrowest trenches. The HOSP surface is lower for the wider trenches.

[image]

The film is then baked on a hot plate for 1 min at a temperature of 350 degree C. (step 9). It is then cured in a horizontal furnace for 1 hour at a temperature of 700 degree C. in a 20%:80% oxygen:nitrogen atmosphere (step 10). During the cure process the organic component of the HOSP films is oxidized and removed, which can be verified using FTIR spectroscopy. A CVD oxide is then deposited (step 11) (5 in structure 14). Because of the benefit of the improved planarization due to the use of the spin-on polymer and the planarization due to the spin rinse process (as compared to the standard CVD only process), a smaller thickness is required for the CVD oxide. Typically an oxide thickness of 20 to 90% of the trench depth is sufficient to achieve the required planarization after the oxide CMP process (step 12) (structure 15).

[image]

[image]

In a subsequent step, the remaining oxide and nitride layer is etched (step 13) (structure 16)

[image]

Among other advantages, it should be appreciated that using contemplated processes, (1) a relatively expensive HDP-CVD process can be eliminated, (2) planarization can be significantly improved through use of a spin-rinse process, (3) oxide thickness can be reduced, thereby decreasing cost for PECVD oxide and time required for CMP.

### STI Process using a Spin-etch Process and Oxide Cap

Steps 1 to 6 of this example are the same as in the example described above. Step 7 is almost the same as in example 3, except that the HOSP film is processed through the full standard bake process (1 min at 150 degree C., 200 degree C., and 350 degree C. each). The wafers are then cured (step 10 of previous example). After the cure process, a spin etch process is used. The spin etch process uses the same process as described in example 2, and is followed by oxide deposition (step 11), CMP (step 12) and etch (step 13).

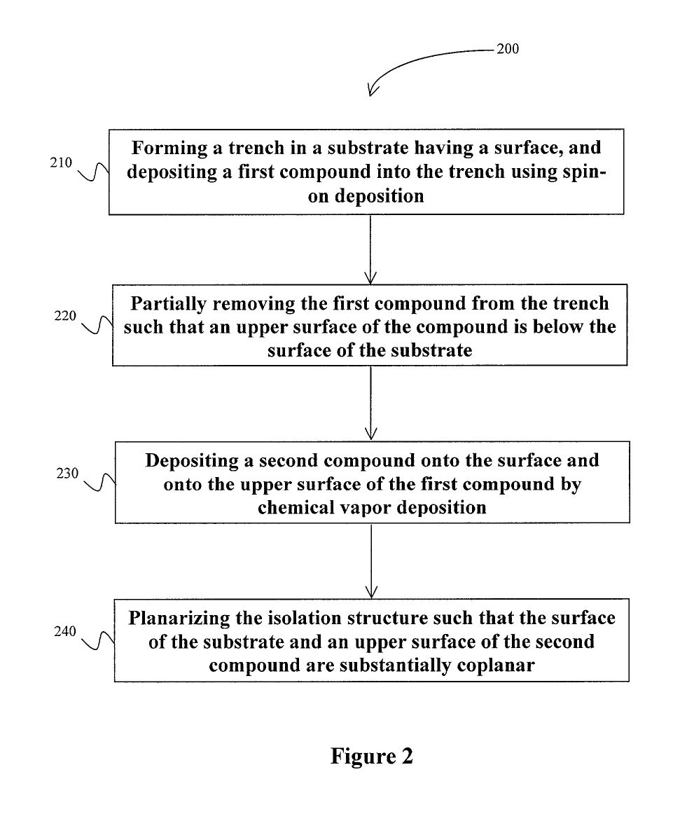

Consequently, it is contemplated that a method of forming a shallow trench isolation structure has one step in which a trench is formed in a substrate having a surface, and a first compound is deposited into the trench using spin-on deposition. In another step, the first compound is at least partially removed from the trench such that an upper surface of the compound is below the surface of the substrate, and in a still further step, a second compound is deposited onto the substrate surface and onto the upper surface of the first compound by chemical vapor deposition. An is exemplary flow chart of contemplated methods is depicted in FIG. 2.

Thus, specific embodiments and applications of electronic devices and their formation have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. An electronic device, comprising:
a substrate having a trench with a lower portion and a top portion; and
wherein the lower portion of the trench is filled with a cured spin-on compound, and the top portion is filled with a chemical vapor-deposited compound.

2. The device of claim 1 wherein the substrate has a surface that is substantially coplanar with a top surface of the chemical vapor-deposited compound.

3. The device of claim 2 wherein the trench further comprises a thermal oxide coat.

4. The device of claim 3 wherein the trench has an aspect ratio (depth/width) of no less than 5.

5. The device of claim 3 wherein the trench has an aspect ratio (depth/width) of no less than 8.

6. The device of claim 1 wherein the spin-on compound comprises silicon.

7. The device of claim 1 wherein the spin-on compound is formed from at least one compound selected from the group consisting of methylsilsesquioxane, hydrogensilsesquioxane, methylhydridosilsesquioxane, silicate, and perhydrosilazane.

8. The device of claim 1 wherein the chemical vapor-deposited compound comprises silicon.

9. The device of claim 1 wherein the chemical vapor-deposited compound is formed from silane or tetraethylorthosilicate.

10. The device of claim 1 wherein the trench has a depth, and wherein the lower portion of the trench extends up to 60% of the depth.

11. The device of claim 1 wherein the trench has a depth, and wherein the lower portion of the trench extends up to 80% of the depth.

12. A method of forming a shallow trench isolation structure, comprising:
forming a trench in a substrate having a surface, and depositing a first compound into the trench using spin-on deposition;
partially removing the first compound from the trench such that an upper surface of the compound is below the surface of the substrate; and
depositing a second compound onto the substrate surface and onto the upper surface of the first compound by chemical vapor deposition.

13. The method of claim 12 further comprising planarizing the isolation structure such that the surface of the substrate and an upper surface of the second compound are substantially coplanar.

14. The method of claim 12 wherein the substrate surface and the trench further comprise a thermal oxide coat.

15. The method of claim 13 wherein the trench has an aspect ratio (depth/width) of no less than 5.

16. The method of claim 12 further comprising curing the first compound to form an oxide.

17. The method of claim 12 wherein the step of partially removing comprises a process selected from the group consisting of a spin-rinse process, a wet etch process, and a dry etch process.

18. The method of claim 12 wherein the first compound is formed from at least one compound selected from the group consisting of methylsilsesquioxane, hydrogensilsesquioxane, methylhydridosilsesquioxane, silicate, and perhydrosilazane.

19. The method of claim 12 wherein the second compound is formed from tetraethylorthosilicate or silane.

20. A method of removing a spin-on compound, comprising:
spin-depositing a spin-on compound on a surface of a substrate; and
spin-rinsing the spin-on compound with a solvent mixture, wherein the solvent mixture comprises a first solvent that dissolves the spin-on compound, and a second solvent that is inert to the spin-on compound.

21. The method of claim 20 further comprising heating the substrate to a first temperature to remove the solvent mixture, and further heating the substrate to a second temperature to cure the spin-on compound.

22. The method of claim 20, wherein the spin-on compound comprises silicon, wherein the first solvent comprises propyl acetate, and wherein the second solvent comprises ethyl lactate.

23. The method of claim 20, wherein the spin-on compound comprises silicon, wherein the first solvent is selected from the group consisting of a ketone, an ester, an ether, a hydrocarbon, and wherein the second solvent is selected from the group consisting of water, an alcohol, acetonitrile, an amine, and an amide.
